(19) United States
(12) Patent Application Publication
(10) Pub. No.: US 2026/0064010 A1
(43) Pub. Date: Mar. 5, 2026

(54) LAYOUT OF CIRCUIT STRUCTURE AND METHOD FOR FORMING CIRCUIT STRUCTURE

(71) Applicant: UNITED MICROELECTRONICS CORP, Hsin-Chu City (TW)

(72) Inventors: Min-Cheng Yang, Tainan City (TW); Chun-Cheng Yu, Pingtung County (TW); Kuan-Wen Fang, Tainan City (TW); Yung-Feng Cheng, Kaohsiung City (TW); Ming-Jui Chen, Tainan City (TW)

(73) Assignee: UNITED MICROELECTRONICS CORP., Hsin-Chu City (TW)

(21) Appl. No.: 18/916,750

(22) Filed: Oct. 16, 2024

(30) Foreign Application Priority Data
Aug. 29, 2024 (TW) 113132470

(51) Int. Cl. G03F 7/00; G03F 1/36; G06F 30/392

(52) U.S. Cl. CPC G03F 7/70466; G03F 1/36; G06F 30/392

(57) ABSTRACT

A method for forming a circuit structure includes decomposing an original layout into a first layout and a second layout, identifying a first pattern-to-cut in the first layout, selecting a first selected segment among the segments of the first pattern-to-cut, and inserting a first cut pattern to the first selected segment. The method further includes, after the first pattern-to-cut subtracting the first cut pattern, outputting the first layout to a first photomask and the second layout and the first cut pattern to a second photomask, and using the first photomask and the second photomask to perform a double patterning process to form the circuit structure on a substrate.

### BACKGROUND OF THE INVENTION

### 1. Field of the Invention

The present invention relates to the field of semiconductor technology, particularly to a layout for a circuit structure and a method for forming a circuit structure using double patterning technology.

### 2. Description of the Prior Art

An integrated circuit (IC) is composed of stacked electronic components and interconnection structures formed by fabricating the feature patterns of the circuit design on a substrate or on material layers disposed on the substrate. Photolithography is one of the most critical processes in IC fabrication, which usually involves exposure and development steps to transfer the designed layout patterns such as patterns of implant/non-implant regions or circuit structures, for example, on a photomask to a photoresist layer on the substrate. The patterned photoresist layer is then utilized as a mask for an ion implantation or etching process, thereby transferring the designed layout patterns to the substrate.

In order provide ICs having smaller sizes and improved performances, the designs of layout patterns of the ICs have become increasingly delicate, wherein the minimized spacing and dimensions of feature patterns have posed significant challenges to the capability of conventional photolithography technology. Multiple patterning technologies, such as double patterning technology (DPT) have been proposed and widely adopted in advanced semiconductor manufacturing technology, which generally include the steps of decomposing an original layout into two or more decomposed layouts, outputting the decomposed layouts to respective photomasks, and using the photomasks to perform photolithography processes to form patterns on the substrate that collectively replicate the original layout. Multiple patterning technologies make it possible to manufacture fine patterns with small critical dimensions and/or minimal spacings using existing exposure equipment.

The multiple patterning techniques illustrated may effectively address the challenges associated with small spacing in the original layout. However, issues related to pattern development anomalies, particularly in negative tone development (NTD), caused by the unique geometry of the feature patterns still require improvement. For example, it has been observed that when the total area of the feature pattern is larger than the development barrier area and the difference between the widths and/or areas of the large and small connected segments of the feature pattern is larger than the development barrier ratio, the said small segment is susceptible to line shrinkage.

### SUMMARY OF THE INVENTION

The present invention is directed to provide a layout for a circuit structure and a method for forming a circuit structure using double patterning technology that may reduce pattern development anomalies by inserting a cutting pattern to a selected segment of the identified risk feature pattern to cut the risk feature pattern into two separated cut portions. These separated cut portions respectively have a width ratio and/or area ratio that does not approach or exceed the development barrier, such that well pattern development may be ensured.

One embodiment of the present invention provides a method for forming a circuit structure including the following steps: decomposing an original layout into a first layout and a second layout, wherein the first layout and the second layout respectively comprise a plurality of feature patterns; identifying a first pattern-to-cut in the first layout, wherein the first pattern-to-cut comprises a plurality of contiguous connected segments; based on a selecting rule, selecting a first selected segment among the segments of the first pattern-to-cut; inserting a first cut pattern to the first selected segment; after subtracting the first cut pattern from the first pattern-to-cut, outputting the first layout to a first photomask, and outputting the second layout and the first cut pattern to a second photomask; and using the first photomask and the second photomask to perform a double patterning process to form the circuit structure on a substrate.

Another embodiment of the present invention provides a layout for a circuit structure including a first pattern comprising a first end portion and a second end portion, wherein the first end has a first width, the second end has a second width, a second first pattern comprising a third end portion and a fourth end portion, wherein the third end portion has the second width and is positioned opposite and separate from the second end portion along a first direction, the fourth end portion has a third width, the third width is smaller than the second width, and the second width is smaller than the first width. The layout for a circuit structure further includes a stitching pattern between the second end portion and the third end portion, wherein the first pattern and the second pattern have a first color to be output to a first photomask, the stitching pattern has a second color to be output to a second photomask.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart illustrating a method for forming a circuit structure according to an embodiment of the present invention.

FIG. 2 to FIG. 11 are schematic diagrams illustrating a method for forming a circuit structure according to an embodiment of the present invention, wherein FIG. 2 to FIG. 6 illustrate the steps of decomposing an original layout and modifying the decomposed layouts, FIG. 7 to FIG. 11 illustrate the steps of using the two photomasks that respectively include the modified decomposed layouts to perform a double patterning process.

### DETAILED DESCRIPTION

To provide a better understanding of the present invention to those of ordinary skill in the art, several exemplary embodiments of the present invention will be detailed as follows, with reference to the accompanying drawings using numbered elements to elaborate the contents and effects to be achieved.

The drawings of the present invention are schematic and not drawn to scale. Some components may be enlarged for clarity. The same reference signs are generally used to refer to corresponding or similar features in modified and different embodiments. The spatial terms mentioned in the specification, such as “below”, “low”, “down”, “above”, “on top”, “over”, “top”, “bottom”, or the like, are understood by those skilled in the art to describe the relative spatial relationships of one component or feature to another (or multiple) components or features in the drawings. Any rotation (such as rotating 90 degrees or other orientations) will still conform to the spatial descriptions in the specification. Reference directions, such as the first direction X and the second direction Y that are perpendicular to each other, are illustrated in some of the drawings to facilitate spatial-related descriptions.

The terms “equal”, “equivalent”, “identical”, or “substantially” are generally interpreted as being within 20% of a given value or range, or interpreted as being within 10%, 5%, 3%, 2%, 1%, or 0.5% of a given value or range. There may be a certain amount of error between any two values or directions used for comparison.

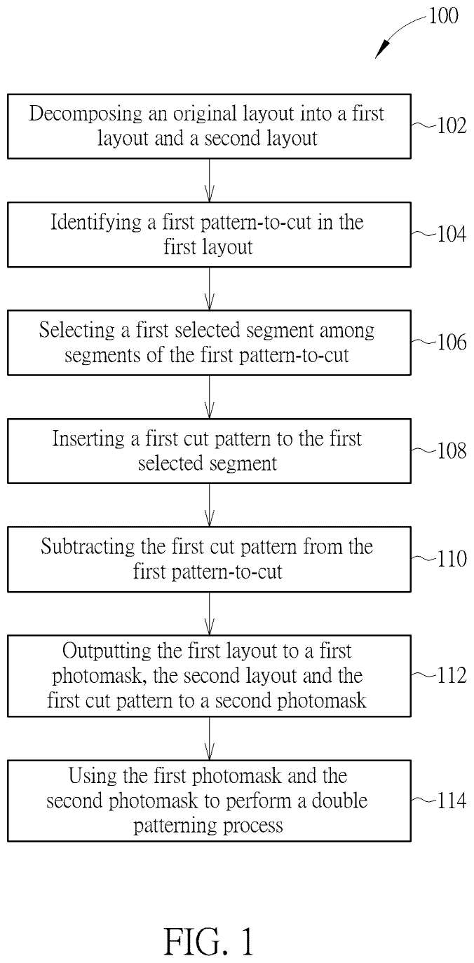

Please refer to FIG. 1. The method 100 for forming a circuit structure includes steps 102, 104, 106, 108, 110, and 114. The steps 102, 104, 106, 108, 110 and 112 are carried out in a computer system. The step 114 is carried out using semiconductor manufacturing equipment. In step 102, an original layout is received in a computer system and decomposed into a first layout and a second layout. Subsequently, in step 104, a first pattern-to-cut in the first layout is identified. In some embodiments of the present invention, a second pattern-to-cut in the second layout is also identified in step 104.

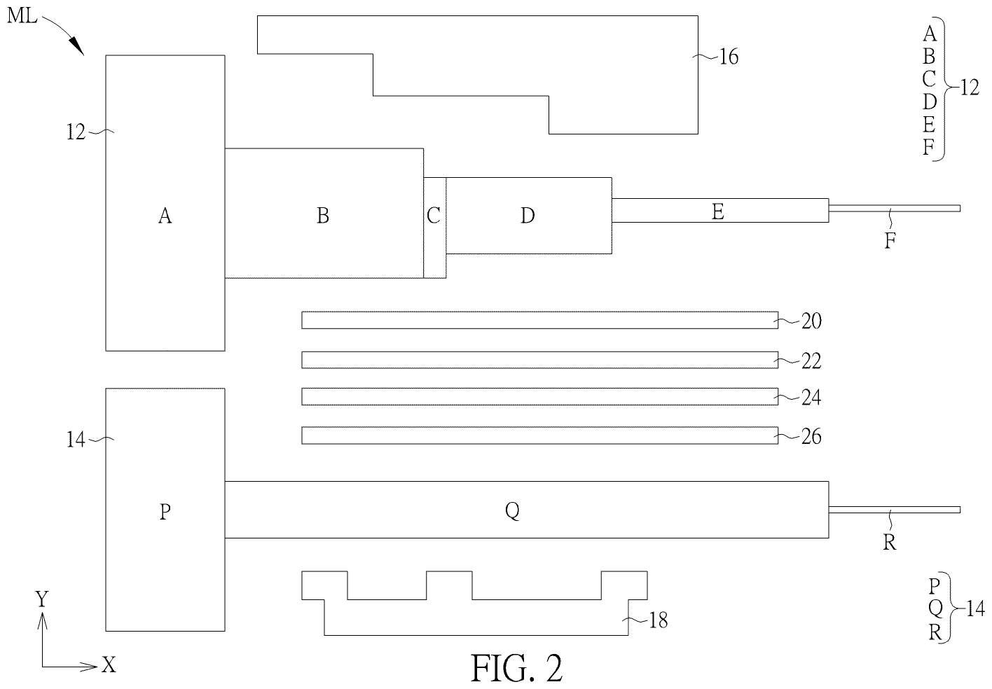

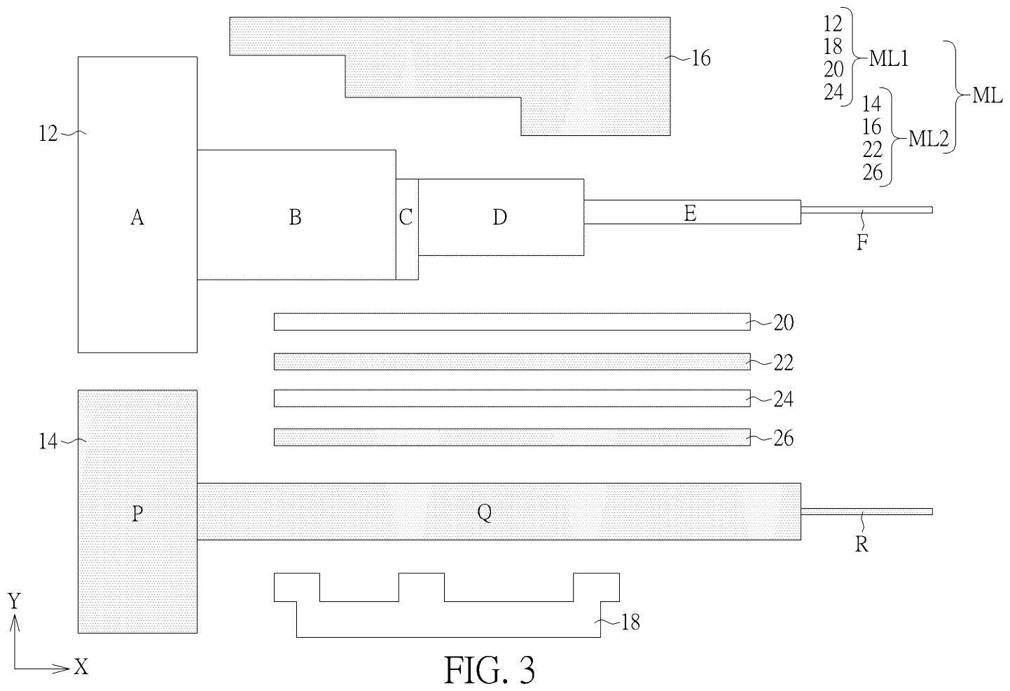

FIG. 2 and FIG. 3 are schematic examples for step 102 and step 104, respectively. As shown in FIG. 2, the original layout ML is received. The original layout ML includes a plurality of feature patterns 12, 14, 16, 18, 20, 22, 24, 26 that are respectively composed of multiple connected rectangular segments. The numbers, shapes and arrangements depicted in the drawings are merely examples, and the present invention is not limited thereto. Besides, the dimensions of the feature patterns are not drawn to scale for clarity in drawing and illustration. The original layout ML includes at least a feature pattern, such as the feature pattern 12, that has a geometry shape and/area that approaches or exceeds the development barrier. The feature pattern 12 includes a plurality of segments A, B, C, D, E, F sequentially connected along the first direction X. In this specification, the length of a segment is defined as the dimension along the first direction X, the width of a segment is defined as the dimension along the second direction Y, and the area of a segment is the product of the length and the width. The lengths and widths of these segments may be the same or different. In some embodiments, these segments are connected in an order of decreasing width, which means that the width of the segment A is the largest among the segments, and the width of the segment F is the smallest among the segments. In some embodiments, the ratio of the width of the segment F to the width of the segment A is smaller than 3/100, or smaller than 2/100, or smaller than 1/100. In some embodiments, the width of the segment F is smaller than or approximately 40 nm, the width of the segment A is larger than or approximately 4000 nm, and the widths of the segments B, C, D, E are between 40 nm and 4000 nm, but are not limited thereto. In some embodiments, the ratio of the area of the segment F to the total area of the other segments A, B, C, D, and E is smaller than 1/1600, or smaller than 1/200. The segment F is also referred to as the minimum segment.

In some embodiments, the original layout ML further includes another feature pattern that approaches or exceeds the development barrier, such as the feature pattern 14 which includes a plurality of segments P, Q, R sequentially connected along the first direction X. The segment R and the segment P may have a width ratio and an area ratio similar to the width ratio and the area ratio between the segment F and the segment A of the feature pattern 12. The segment R is also referred to as the minimum segment.

It should be noted that the feature patterns 12, 14, 16, 18, 20, 22, 24, and 26 may respectively be an isolated pattern that is physically separated from other feature patterns, or be connected to at least one of the other feature patterns, or be part of another feature pattern. For example, the segment A and the segment F may respectively be an end segment of the feature pattern 12, or may be connected to another segment (not shown) of the feature pattern 12 or to another feature pattern. Similarly, the segment P and the segment R may respectively be an end segment of the feature pattern 14, or be connected to another segment (not shown) of the feature pattern 14 or to another feature pattern. In this embodiment, the segments A, B, C, D, E and F are defined by zigzag points of the edges of the feature pattern 12. The segments P, Q, R are defined by zigzag points of the edges of the feature pattern 14. In other embodiments, the segments of the feature pattern may be defined by other suitable method.

As shown in FIG. 3, the original layout ML is decomposed into a first layout ML1 and a second layout ML2. The first layout ML 1 includes the feature patterns 12, 18, 20, 24 that are colored in a first color. The second layout ML2 includes the feature patterns 14, 16, 22, 26 that are colored in a second color. The method of decomposing the original layout ML may be designed based on design specifications and manufacturing process capability, which will not be detailed herein. The first layout ML1 and the second layout ML2 are then subjected to a verification to identify the feature pattern 12 and the feature pattern 14 that have higher risk of development anomalies as the pattern-to-cut in the first layout ML1 and the pattern-to-cut in the second layout ML2, respectively.

Please refer to FIG. 1. Subsequently, in step 106, a first selected segment among the segments of the first pattern-to-cut is selected based on a selecting rule. In some embodiments, a second selected segment among the segments of the second pattern-to-cut is also selected based on the selecting rule in the step 106. In some embodiments, the selecting rule includes a spacing rule that the spacing between the selected segment and other feature patterns in the same layout is smaller than a first predetermined value, and the spacing between the selected segment and the feature patterns in the other layout is larger than a second predetermined value, wherein the first predetermined value is smaller than the second predetermined value. In some embodiments, the selecting rule further includes a dimension rule that a segment having a longer length and a smaller width has a higher selection priority. In some embodiments, the selecting rule further includes excluding the smallest segment among the segments.

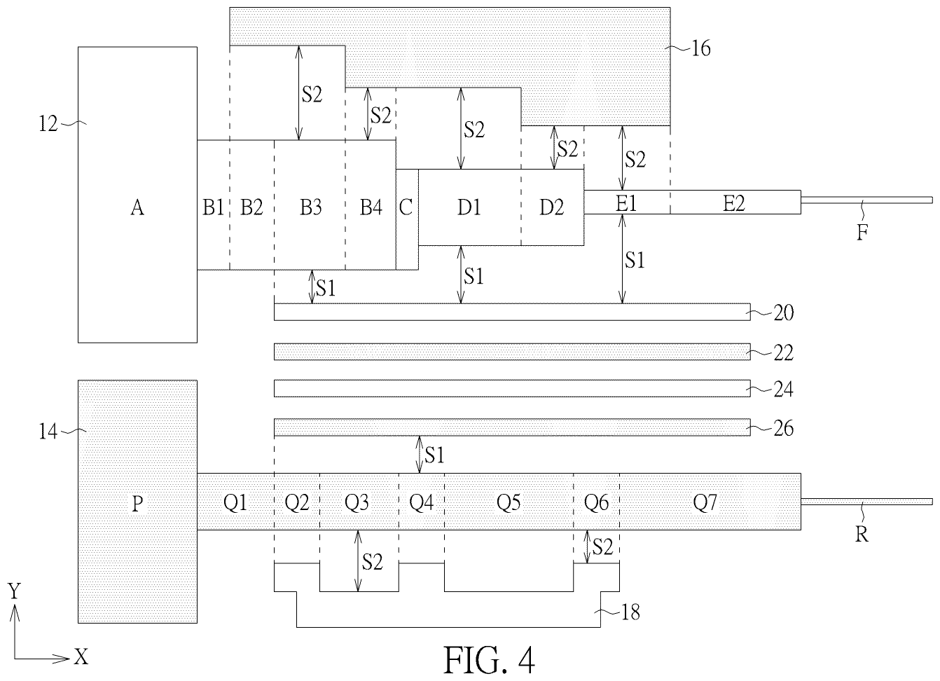

FIG. 4 is a schematic diagram illustrating the step 106. The step to determine the selected segment from the segments A, B, C, D, E of the feature pattern 12 in the first layout ML1 includes checking the spacings S1 in the second direction Y between the feature pattern 12 and the other feature patterns adjacent to the feature pattern 12 in the first layout ML1, and the spacings S2 in the second direction Y between the feature pattern 12 and the feature patterns in the second layout ML2 and adjacent to the feature pattern 12. The feature pattern 12 is then divided into smaller segments based on the spacings S1 and the spacings S2. For example, the segment B is divided into segments B1, B2, B3 and B4 based on different spacings S2. The segment D is divided into segments D1 and D2 based on spacings S2. The segment E is divided into segments E1 and E2 based on spacings S1 and S2. Subsequently, the segment having spacings S1 smaller than the first pre-determined value and spacings S2 larger than the second pre-determined value is determined as the selected segment. For example, the segments A, B1, B2, E1 and E2 are not selected due to violating the rule that the spacings S1 must be smaller than the first pre-determined value. The segments B4 and D2 are not selected due to violating the rule that the spacings S2 must be larger than the second pre-determined value. According to an embodiment of the present invention, the first pre-determined value is approximately 70 nm, the second pre-determined value is approximately 90 nm, but are not limited thereto. Among the segments B3, C and D1 that meet the spacing rule, the segment D1 has a higher selection priority based on the dimension rule.

Similarly, the step to determine the selected segment from the segments P, Q, R of the feature pattern 14 in the second layout ML2 includes checking the spacings S1 in the second direction Y between the feature pattern 14 and the feature patterns in the first layout ML1 and adjacent to the feature pattern 14, and the spacings S2 between the feature pattern 14 and the other patterns in the second layout and adjacent to the feature pattern 14. The feature pattern 14 is then divided into smaller segments based on the spacings S1 and S2. For example, the segment Q is divided into segments Q1, Q2, Q3, Q4, Q5, Q6 and Q7. Subsequently, the segments Q3, Q5 and Q7 are preliminary selected based on the spacing rule that the spacing S1 must be smaller than the first pre-determined value and the spacings S2 must be larger than the second pre-determined value. Following, based on the dimension selecting rule, the segment Q7 having longer length is determined as the selected segment.

Please refer to FIG. 1. In step 108, a first cutting pattern is inserted to the first pattern-to-cut. In some embodiment, a second cutting pattern is inserted to the second pattern-to-cut.

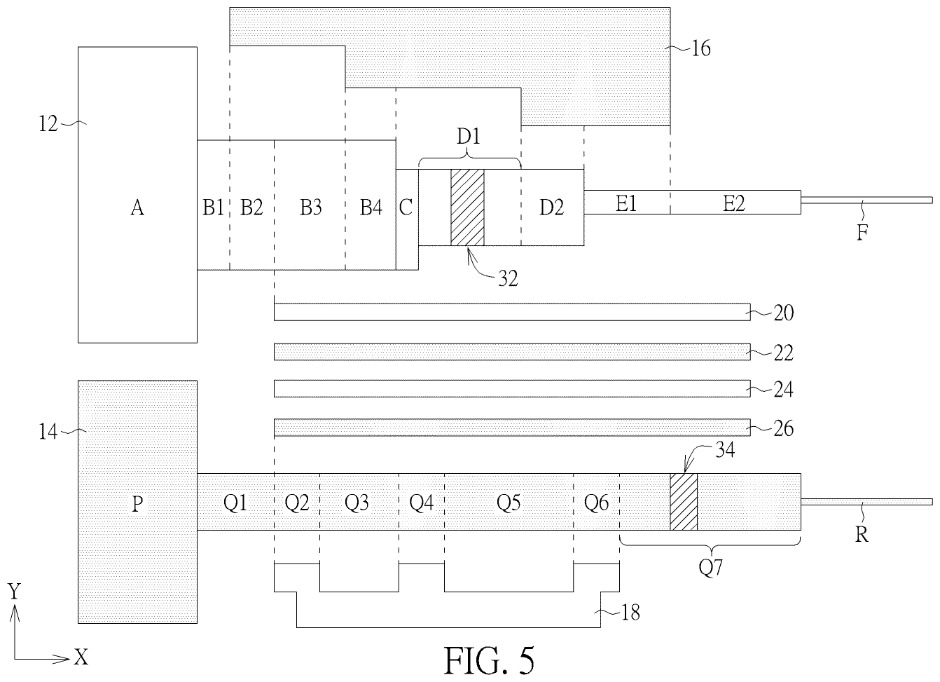

FIG. 5 is a schematic diagram illustrating the step 108. After determining the selected segment D1 (the first selected segment) of the feature pattern 12, a cutting pattern 32 (the first cutting pattern) is inserted to the segment D1. The feature pattern 12 is cut into two separate cut portions by subtracting the region of the feature pattern 12 overlapped with the cutting pattern 32. Similarly, a cutting pattern 34 (the second cutting pattern) may be inserted to the selected segment Q7 (the second selected segment) of the feature pattern 14 to cut the feature pattern 14 into two separate cut portions by subtracting the region overlapped with the cutting pattern 34. The shapes and sizes of the cutting patterns 32 and 34 may be adjusted according to design needs. In some embodiments, the cutting patterns 32 and 34 are rectangular, with lengths and widths in compliance with the design rules of the first layout ML1 and the second layout ML2.

Please refer to FIG. 1. The method 100 for forming the circuit structure continues to step 110, wherein a portion of the first pattern-to-cut overlapped with the first cutting pattern is subtracted from the first pattern-to-cut. Subsequently, in step 112, the first layout is output to a first photomask, and the second layout and the first cutting pattern are output to a second photomask. In some embodiments, the step 110 also includes subtracting the portion of the second pattern-to-cut overlapped with the second cutting pattern from the second pattern-to-cut, and the step 112 also includes outputting the second cutting pattern to the first photomask.

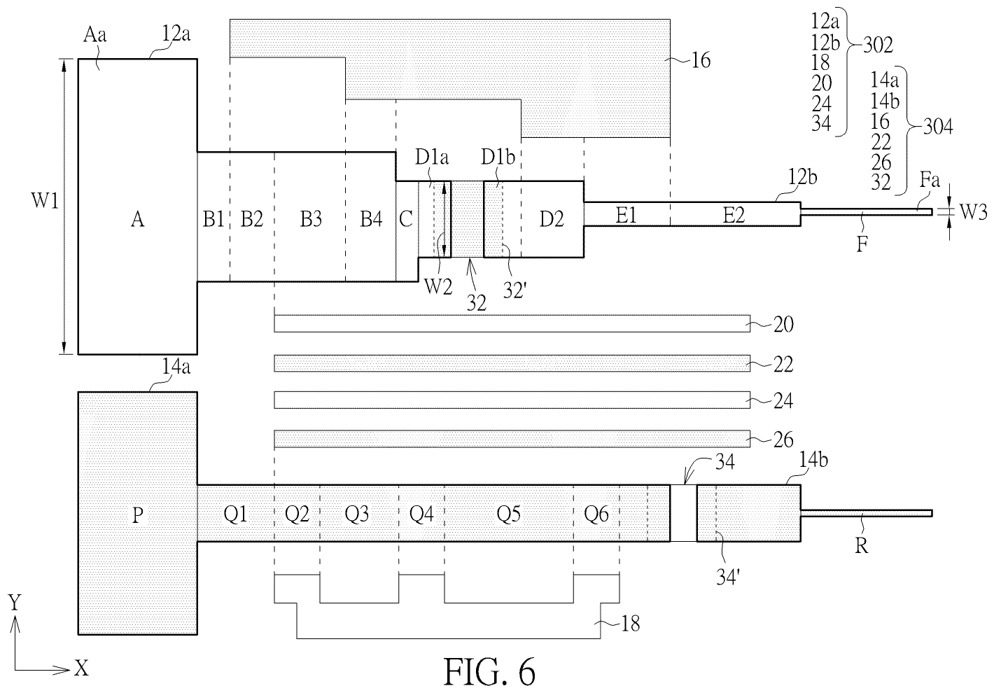

FIG. 6 is a schematic diagram illustrating the step 112. As shown in FIG. 6, by subtracting the cutting pattern 32 from the feature pattern 12, the feature pattern 12 is cut into two separate cut portions, namely the feature patterns 12a and 12b. The feature patterns 12a and 12b and the other feature patterns 18, 20, and 24 of the first layout ML1 are then output to a first photomask 302. In some embodiments, by subtracting the cutting pattern 34 from the feature pattern 14, the feature pattern 14 is cut into two separate cut portions, namely the feature patterns 14a and 14b. The feature patterns 14a and 14b and the other feature patterns 16, 22, and 26 of the second layout ML are then output to a second photomask 304. It is noteworthy that the cutting pattern 32 is colored in the second color and output to the second photomask 304, and the cutting pattern 34 is colored in the first color and output to the first photomask 302. Before being output to the photomasks, these feature patterns and cutting patterns may be modified by optical proximity correction (OPC), such as corner rounding, line end expanding/shortening, and line width expending/narrowing, but are not limited thereto. In some embodiments, the cutting patterns 32 and 34 may be elongated along the first direction X, turning into the cutting pattern 32′ that partially overlaps the feature patterns 12a and 12b and the cutting pattern 34′ that partially overlaps the feature patterns 14a and 14b. The cutting pattern 32′ and the cutting pattern 34′ are then output to the second photomask 304 and the first photomask 302, respectively.

Please refer to FIG. 1. Subsequently, in step 114, a double patterning process using the first photomask and the second photomask is performed to form the circuit structure on a substrate.

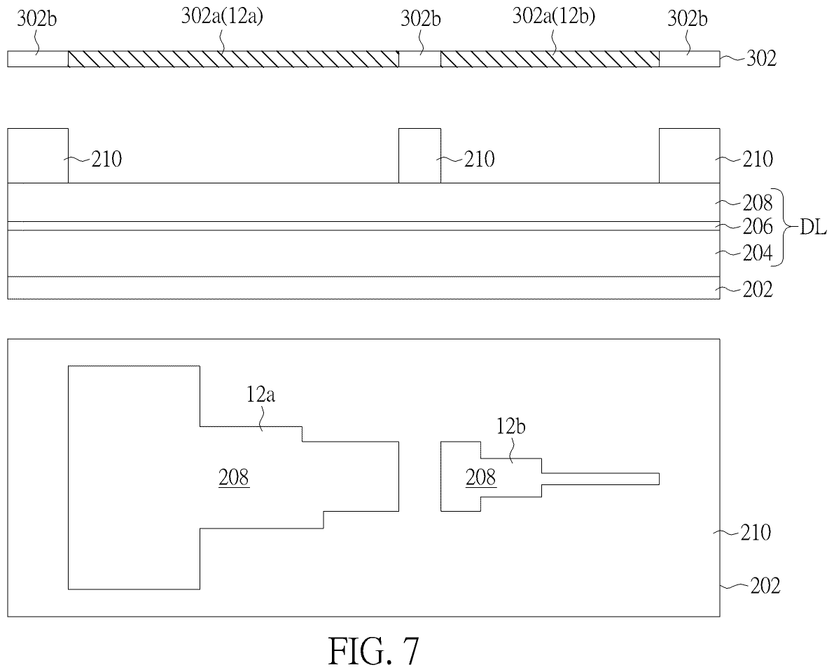

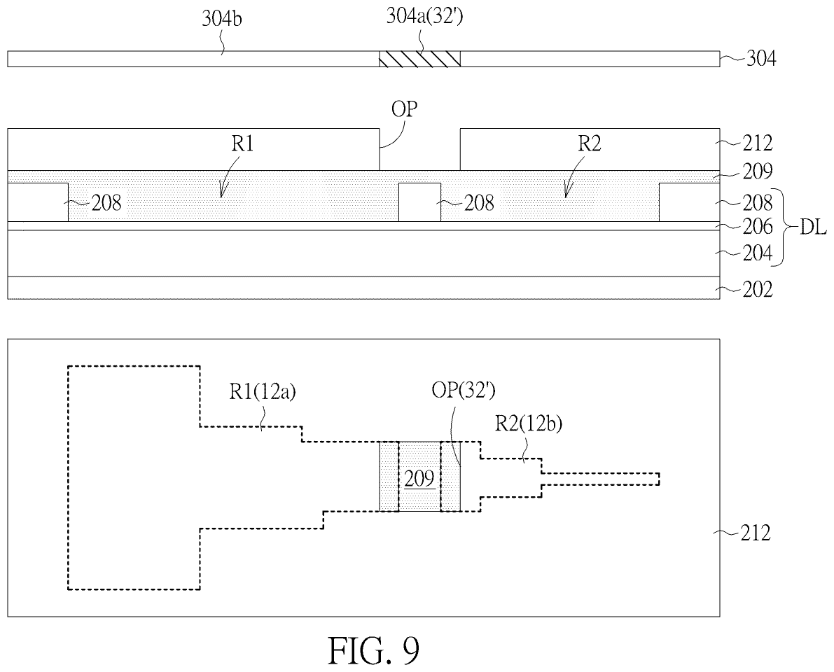

FIG. 7 to FIG. 10 are schematic diagrams exemplarily illustrating the double patterning process in step 114, which uses a first photomask 302 and a second photomask 304 to form a circuit structure M1 on a substrate 202. The upper portions of FIG. 7 to FIG. 10 are cross-sectional views. The lower portions of FIG. 7 to FIG. 10 are plan views. As shown in the upper portion of FIG. 7, the first photomask 302 includes opaque patterns 302a and clear patterns 302b. The feature patterns 12a, 12b, 18, 20, and 24 and the cutting pattern 34 (or the cutting pattern 34′) are the opaque regions 302a of the first photomask 302. As shown in the upper portion of FIG. 9, the second photomask 304 includes opaque patterns 304a and clear patterns 304b. The feature patterns 14a, 14b, 16, 22, and 26 and the cutting pattern 32 (or the cutting pattern 32′) are the opaque patterns 304a of the second photomask 304. The circuit structure M1 may be an interconnection structure formed in a dielectric layer DL on the substrate 202, but is not limited thereto.

It should be noted that, the double patterning process in this embodiment uses positive-type photoresist for pattern exposure and negative tone development (NTD) for pattern development. The double patterning process may include twice exposure-development-etching steps (2P2D2E) using two photoresist layers. In other embodiments, the double patterning process may include twice exposure-development steps and once etching using one or two photoresist layers, but is not limited thereto. Although in FIG. 7 to FIG. 10, only the pattern transfer process of the feature patterns 12a, 12b and the cutting pattern 32′ are illustrated, it should be understood that other patterns such as the feature patterns 14a, 14b and the cutting pattern 34 may also be transferred to the substrate by similar process.

As shown in FIG. 7, a dielectric layer DL is formed on a substrate 202. A first photoresist layer 210 is formed on the dielectric layer DL. The substrate 202 may be a silicon substrate, a silicon-on-insulator (SOI) substrate, or a group III-V semiconductor substrate, but is not limited thereto. The substrate 202 may include manufactured semiconductor components, such as transistors, capacitors, resistors, inductors, etc., which are not shown in the diagrams for the sake of simplification. The dielectric layer DL may have a multi-layer structure, and from bottom to top may include dielectric layers 204, 206, and 208. The dielectric layers 204 and 208 may respectively be made of silicon oxide (SiO₂) or a suitable low-k dielectric material such as fluorinated silica glass (FSG), silicon oxycarbide (SiCOH), spin-on-glass, porous low-k dielectric material, organic dielectric polymers, or a combination thereof, but is not limited thereto. The dielectric layer 206 is made of a material different from the dielectric layer 206, such as silicon nitride (SiN), silicon carbonitride (SiCN), silicon oxynitride (SiON), or a combination thereof, but is not limited thereto. The number of layers of the dielectric layer DL illustrated herein is an example, and the present invention is not limited thereto. In other embodiments, the dielectric layer DL may include number of layers different from the above example, or may have a single-layer structure. The first photoresist layer 210 may be any suitable positive-type photoresist. Subsequently, the first photoresist layer 210 is patterned by a first exposure using the first photomask 302 and a negative tone development (NTD) to remove the unexposed portions of the first photoresist layer 210, thereby transferring the opaque patterns 302a of the first photomask 302 to the first photoresist layer 210. Accordingly, the feature patterns 12a and 12b are defined in the first photoresist layer 210.

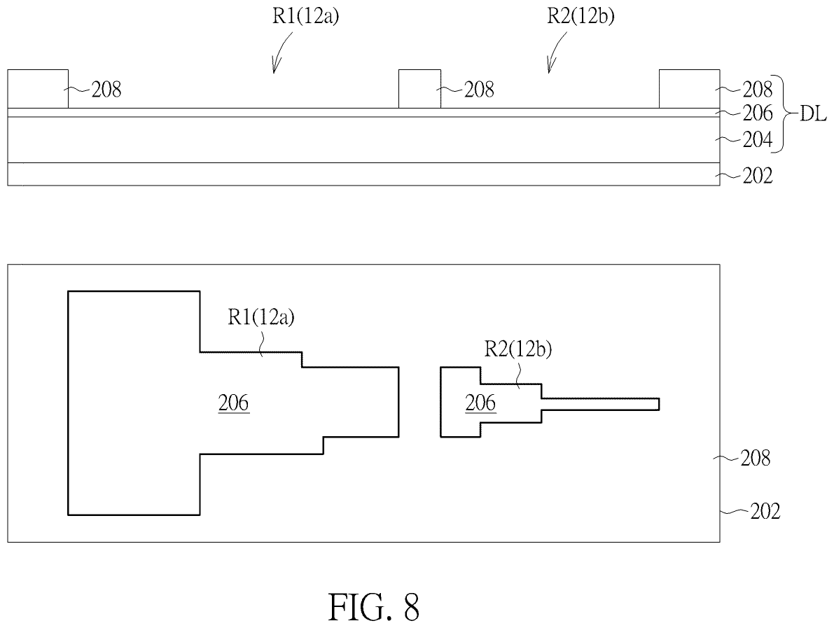

As shown in FIG. 8, an etching process using the first photoresist layer 210 as an etching mask is performed to etch the portions of the dielectric layer 208 exposed from the first photoresist layer 210 until the dielectric layer 206 is exposed, thereby transferring the patterns of the first photoresist layer 210 to the dielectric layer 208 and forming a trench R1 and a trench R2 respectively defined by the feature pattern 12a and the feature pattern 12b in the dielectric layer 208. The dielectric layer 206 serves as an etching stop layer during the etching process, ensuring that the trenches R1 and R2 may have uniform depths. The remaining first photoresist layer 210 is removed after forming the trenches R1 and R2.

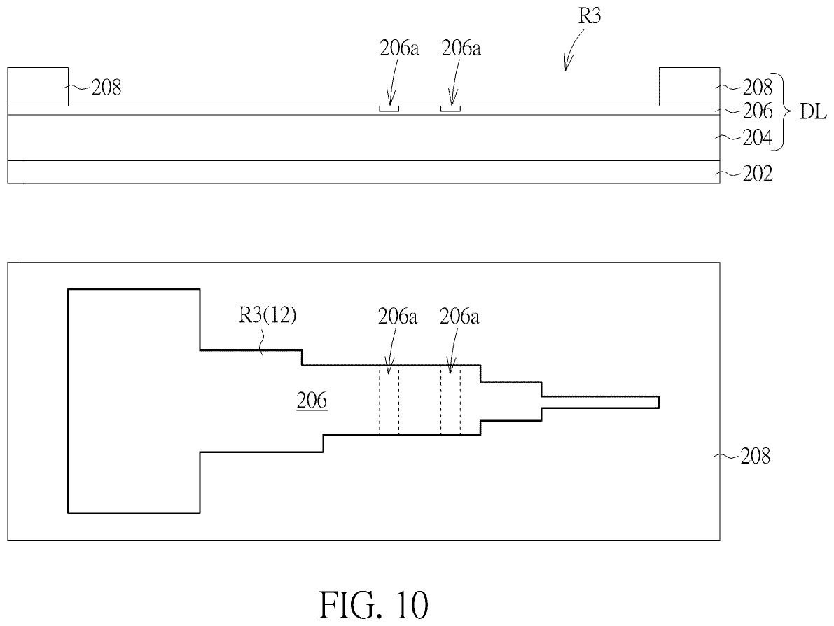

Subsequently, as shown in FIG. 9, a planarization layer 209 is formed on the dielectric layer 208 and filling into the trenches R1 and R2. A second photoresist layer 212 is formed on the planarization layer 209. The second photoresist layer 212 is patterned by a second exposure using the second photomask 304 and a negative tone development (NTD) to remove the unexposed portions of the second photoresist layer 212, thereby transferring the opaque patterns 304a of the second photomask 304 to the second photoresist layer 212. Accordingly, an opening OP defined by the cutting pattern 32′ is defined in the second photoresist layer 212. The planarization layer 209 may include an organic dielectric layer (ODL), an optical planarization layer (OPL), a spin-on hard mask (SOH), and/or an advanced patterning film (APF). The material of the planarization layer 209 must have a high etch selectivity over the dielectric layers 208 and 206, so that the planarization layer 209 may be conveniently removed using a selective etching process after forming the trench R3 (shown in FIG. 10) in later process.

As shown in FIG. 10, an etching process using the second photoresist layer 212 as an etching mask is performed to etch the planarization layer 209 and the exposed from the opening OP and the dielectric layer 208 between the trench R1 and the trench R2 until the dielectric layer 206 is exposed, so that the trench R1 and the trench R2 are connected to form a continuous trench R3. After forming the trench R3, the remaining second photoresist layer 212 and planarization layer 209 are removed. The pattern of the trench R3 is the same as the feature pattern 12. In some embodiments, the etching process through the opening OP may have different rates for the planarization layer 209 and the dielectric layer 208, resulting in recesses 206a in the dielectric layer 206. Please refer to FIG. 9 and FIG. 10, the locations of the recesses 206a approximately correspond to the locations where the feature patterns 12a and 12b overlap with the cutting pattern 32′.

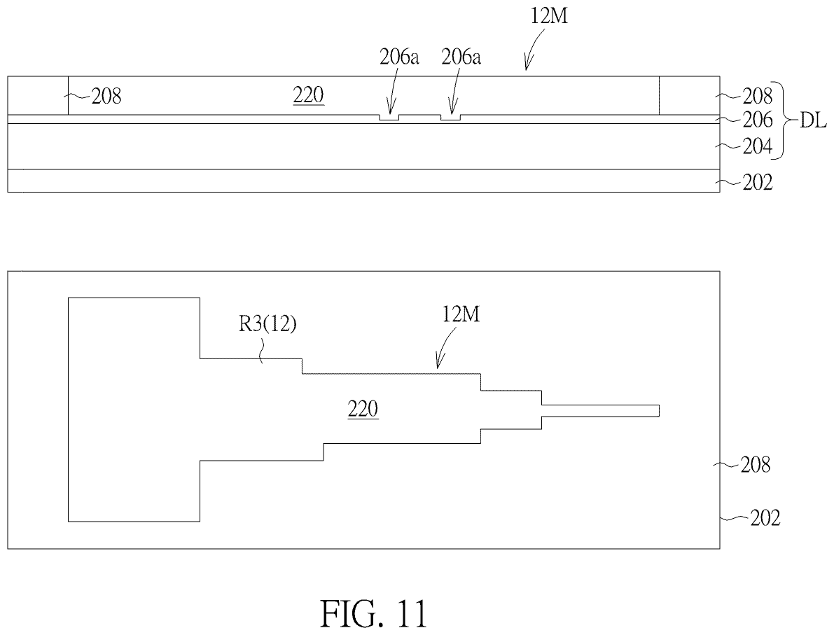

Subsequently, as shown in FIG. 11, a conductive material 220 is formed on the dielectric layer 208 and filling up the trench R3. A removal process such as an etching process or chemical mechanical polishing process is performed to remove the conductive material 220 outside the trench R3, obtaining the circuit structure 12M in the trench R3. The conductive material 220 may include a metal, such as copper (Cu), but is not limited thereto.

In summary, the present invention provides a method for forming a circuit structure, which is characterized by inserting a cutting pattern to a selected segment of a feature pattern of an original layout, cutting the feature pattern into two separate cut portions by subtracting the region of the feature pattern overlapped by the cutting pattern, outputting the portions of the feature pattern and the cutting pattern respectively to two different photomasks, and using the two photomasks to perform a double patterning process to form patterns on a substrate that collectively form the original feature pattern. The separated cut portions of the feature pattern respectively have a width ratio and/or area ratio that does not approach or exceed the development barrier, such that the issue of development anomalies may be resolved.

The present invention further provides a layout for a circuit structure including, as shown in FIG. 6, a first pattern 12a, a second pattern 12b, and a stitching pattern 32′ (also referred to as the cutting pattern) between the first pattern 12a and the second pattern 12b. The first pattern 12a includes a first end portion Aa and a second end portion D1a, wherein the first end portion Aa has a first width W1, the second end portion D1a has a second width W2. The second pattern 12b includes a third end portion D1b and a fourth end portion Fa. The third end portion D1b has the second width W2 and is opposite and separate from the second end portion D1a along a first direction X. The fourth end portion Fa has a third width W3. The third width W3 is smaller than the second width W2, and the second width W2 is smaller than the first width W1. The first pattern 12a and the second pattern 12b have a first color to be output to a first photomask 302. The stitching pattern 32′ has a second color to be output to a second photomask 304.

In some embodiments, the first photomask 302 and the second photomask 304 are used for a double patterning process. A total area of the first pattern 12a, the second pattern 12b and the stitching pattern 32′ is larger than a development barrier area of the double patterning process.

In some embodiments, a width of the first pattern 12a gradually decreases from the first end portion Aa to the second end portion D1a, and a width of the second pattern 12b gradually decreases from the third end portion D1b to the fourth end portion Fa.

In some embodiments, a ratio of the third width W3 to the first width W1 is smaller than 1/100. In some embodiments, the third width W3 is smaller than 40 nm, and the first width W1 is larger than 4000 nm.

In some embodiments, a ratio of an area of the second pattern 12b to an area of the first pattern 12a is smaller than 1/2000.

In some embodiments, the stitching pattern 32′ partially overlaps the second end portion D1a of the first pattern 12a and the third end portion D1b of the second pattern 12b. In some embodiments, an edge of the second end portion D1a, an edge of the stitching pattern 32′, and an edge of the third end portion D1b are aligned along the first direction X.

In some embodiments, the layout for a circuit structure further includes a plurality of third patterns 18, 20, 24 having the first color, wherein the stitching pattern 32′ is adjacent to the third pattern 20, and a spacing S1 (referring to FIG. 4) between the stitching pattern 32′ and the third pattern 20 is smaller than a smallest spacing between the third patterns 18, 20, 24.

In some embodiments, the layout for a circuit structure further includes a plurality of fourth patterns 16, 22, 26 having the second color, wherein the stitching pattern 32′ is adjacent to the fourth pattern 16, and a spacing S2 between the stitching pattern 32′ and the fourth pattern 16 is larger than a smallest spacing between the fourth patterns 16, 22, 26.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a circuit structure, comprising:
decomposing an original layout into a first layout and a second layout, wherein the first layout and the second layout respectively comprise a plurality of feature patterns;
identifying a first pattern-to-cut in the first layout, wherein the first pattern-to-cut comprises a plurality of contiguous connected segments;
based on a selecting rule, selecting a first selected segment among the segments of the first pattern-to-cut;
inserting a first cut pattern to the first selected segment;
after subtracting the first cut pattern from the first pattern-to-cut, outputting the first layout to a first photomask, and outputting the second layout and the first cut pattern to a second photomask; and
using the first photomask and the second photomask to perform a double patterning process to form the circuit structure on a substrate.

2. The method for forming a circuit structure according to claim 1, wherein a total area of the first pattern-to-cut is larger than a development barrier area of the double patterning process.

3. The method for forming a circuit structure according to claim 1, wherein the segments of the first pattern-to-cut are connected in an order of decreasing width.

4. The method for forming a circuit structure according to claim 3, wherein a ratio of a minimum width to a maximum width of the first pattern-to-cut is smaller than 1/100.

5. The method for forming a circuit structure according to claim 4, wherein the minimum width is smaller than 40 nm, the maximum width is larger than 4000 nm.

6. The method for forming a circuit structure according to claim 3, wherein among the segments of the first pattern-to-cut, a ratio of an area of a smallest segment to a total area of the other segment is smaller than 1/2000.

7. The method for forming a circuit structure according to claim 1, wherein the selecting rule comprises:
being spaced from adjacent feature patterns of the same layout smaller than a first predetermined value; and
being spaced from adjacent feature patterns of the other layout larger than a second predetermined value, wherein the first predetermined value is smaller than the second predetermined value.

8. The method for forming a circuit structure according to claim 7, wherein the selecting rule further comprises:
selecting a segment with a longer length.

9. The method for forming a circuit structure according to claim 7, wherein the selecting rule further comprises:
selecting a segment with a smaller width.

10. The method for forming a circuit structure according to claim 1, further comprising:
identifying a second pattern-to-cut in the second layout;
based on the selecting rule, selecting a second selected segment of the second pattern-to-cut;
inserting a second cut pattern to the second selected segment; and
after subtracting the second cut pattern from the second pattern-to-cut, outputting the second layout to the second photomask, and outputting the first layout and the second cut pattern to the first photomask.

11. A layout for a circuit structure, comprising:
a first pattern comprising a first end portion and a second end portion, the first end having a first width, the second end having a second width;
a second first pattern comprising a third end portion and a fourth end portion, wherein the third end portion has the second width and is positioned opposite and separate from the second end portion along a first direction, the fourth end portion has a third width, the third width is smaller than the second width, and the second width is smaller than the first width; and
a stitching pattern between the second end portion and the third end portion, wherein the first pattern and the second pattern have a first color to be output to a first photomask, the stitching pattern has a second color to be output to a second photomask.

12. The layout for a circuit structure according to claim 11, wherein the first photomask and the second photomask are used for a double patterning process, and a total area of the first pattern, the second pattern and the stitching pattern is larger than a development barrier area of the double patterning process.

13. The layout for a circuit structure according to claim 11, wherein a width of the first pattern gradually decreases from the first end portion to the second end portion, and a width of the second pattern gradually decreases from the third end portion to the fourth end portion.

14. The layout for a circuit structure according to claim 11, wherein a ratio of the third width to the first width is smaller than 1/100.

15. The layout for a circuit structure according to claim 14, wherein the third width is smaller than 40 nm, the first width is larger than 4000 nm.

16. The layout for a circuit structure according to claim 11, wherein a ratio of an area of the second pattern to an area of the first pattern is smaller than 1/2000.

17. The layout for a circuit structure according to claim 11, wherein the stitching pattern partially overlaps the second end portion and the third end portion.

18. The layout for a circuit structure according to claim 11, wherein an edge of the second end portion, an edge of the stitching pattern, and an edge of the third end portion are aligned along the first direction.

19. The layout for a circuit structure according to claim 11, further comprising:
a plurality of third patterns having the first color, wherein the stitching pattern is adjacent to one of the third patterns, and a spacing between the stitching pattern and the one of the third patterns is smaller than a smallest spacing between the third patterns.

20. The layout for a circuit structure according to claim 11, further comprising:
a plurality of fourth patterns having the second color, wherein the stitching pattern is adjacent to one of the fourth patterns, and a spacing between the stitching pattern and the one of the fourth patterns is larger than a smallest spacing between the fourth patterns.
